(19) United States
(12) Patent Application Publication
(10) Pub. No.: US 2025/0133948 A1
(43) Pub. Date: Apr. 24, 2025

(54) DISPLAY MODULE

(71) Applicant: SAMSUNG DISPLAY CO., LTD., YONGIN-SI (KR)

(72) Inventors: HUN TAE KIM, Yongin-si (KR); MYOUNG HO KWON, Yongin-si (KR); CHEOL YEONG PARK, Yongin-si (KR); KYUNG MOK LEE, Yongin-si (KR)

(21) Appl. No.: 18/922,543

(22) Filed: Oct. 22, 2024

(30) Foreign Application Priority Data
Oct. 24, 2023 (KR) 10-2023-0143266

(51) Int. Cl. H10K 71/70; H10K 59/131; H10K 59/95

(52) U.S. Cl. CPC H10K 71/70; H10K 59/131; H10K 59/95

(57) ABSTRACT

A display module includes: a display panel including a plurality of output pad groups each output pad group of the plurality of output pad groups including a first output pad; and a driving circuit chip disposed on the display panel and overlapping the output pad groups; a printed circuit board disposed on the display panel, the printed circuit board including a plurality of output terminals electrically connected to the plurality of output pad groups. The plurality of output terminals include a first output terminal electrically connected to the first output pad of each of the plurality of output pad groups.

### CROSS-REFERENCE TO RELATED APPLICATION

The present application claims priority under 35 U.S.C. § 119(a) to Korean patent application No. 10-2023-0143266, filed on Oct. 24, 2023, in the Korean Intellectual Property Office, the entire disclosure of which is herein incorporated by reference.

### BACKGROUND

### 1. Technical Field

The present disclosure generally relates to a display module, and more particularly, to a display module having wiring enabling the performance of a connection resistance test.

### 2. Discussion of Related Art

An integrated circuit for driving light emitting elements in a display module may be disposed on a display panel. The integrated circuit may be mounted directly on the display panel in, for example, a Chip-On-Glass (COG) structure or a Chip-On-Plastic (COP) structure, which may increase the ratio of a display area occupied in the display panel. In addition, a printed circuit board may be disposed on the display panel in a Film-On-Plastic (FOP) structure or a Film-On-Glass (FOG) structure.

When the integrated circuit is mounted directly on the display panel in a COP structure, a connection resistance may be generated between the display panel and the integrated circuit. In addition, when the printed circuit board is disposed on the display panel, a connection resistance may be generated between the display panel and the printed circuit board.

### SUMMARY

Embodiments provide a display module including a printed circuit board having an improved design enabling the performance of a connection resistance test.

In accordance with an aspect of the present disclosure, there is provided a display module including: a display panel including a plurality of output pad groups each output pad group of the plurality of output pad groups including a first output pad; a driving circuit chip disposed on the display panel and overlapping the plurality of output pad groups; and a printed circuit board disposed on the display panel, the printed circuit board including a plurality of output terminals electrically connected to the plurality of output pad groups, wherein the output terminals include a first output terminal electrically connected to the first output pad of each of the output pad groups.

Each output pad group of the plurality of output pad groups may include a grounded second output pad.

The plurality of output terminals may further include a second output terminal electrically connected to the grounded second output pad of each output pad group of the plurality of output pad groups. A current supplied to the first output pad of each output pad group of the plurality of output pad groups through the first output terminal may flow from the first output terminal to the second output terminal.

Each output pad group of the plurality of output pad groups may include a third output pad and a fourth output pad. The plurality of output terminals may include a plurality of third output terminals electrically connected to the third output pad of each output pad group of the plurality of output pad groups and a fourth output terminal electrically connected to the fourth output pad of each output pad group of the plurality of output pad groups.

A test device may be electrically connected to the printed circuit board, and the test device may measure a resistance between the grounded second output pad of at least one output pad group of the plurality of output pad groups and the driving circuit chip.

The test device may measure, as the resistance, a value obtained by dividing a potential difference between at least one of the fourth output pads and at least one of the third output pads by the current.

The display panel may further include a plurality of input pad groups each including a first input pad. The printed circuit board may include a plurality of input terminals connected to the plurality of input pad groups. The plurality of input terminals may include first input terminals electrically connected to the first input pad of each input pad group of the plurality of input pad groups.

A current may be supplied to the first input pad of each input pad group of the plurality of input pad groups through the plurality of first input terminals.

Each of the input pad groups may include a grounded second input pad.

The plurality of input terminals may further include a second input terminal electrically connected to the second input pad of each input pad group of the plurality of input pad groups. The current may flow from the plurality of first input terminals to the second input terminal.

The second output terminal and the second input terminal may be a same terminal.

Each input pad group of the plurality of input pad groups may include a third input pad and a fourth input pad. The plurality of input terminals may include a plurality of third input terminals electrically connected to the third input pad of each input pad group of the plurality of input pad groups and a fourth input terminal electrically connected to the fourth input pad of each input pad group of the plurality of input pad groups.

A test device may be electrically connected to the printed circuit board, and the test device may measure a resistance between the second input pad of at least one input pad group of the plurality of input pad groups and the printed circuit board.

The test device may measure, as the resistance, a value obtained by dividing a potential difference between at least one of the fourth input pads and at least one of the third input pads by the current.

The driving circuit chip may be disposed in a Chip-On-Plastic (COP) structure or a Chip-On-Glass (COG) structure. The printed circuit board may be disposed in a Film-On-Plastic (FOP) structure or a Film-On-Glass (FOG) structure.

In accordance with another aspect of the present disclosure, there is provided a display module including: a display panel including a plurality of input pad groups each including a first input pad and a grounded second input pad; and a printed circuit board disposed on the display panel, the printed circuit board including a plurality of input terminals connected to the plurality of input pad groups, wherein the plurality of input terminals include a plurality of first input terminals electrically connected to the first input pad of each of the input pad groups and a second input terminal electrically connected to the grounded second input pad of each of the input pad groups.

Each input pad group of the plurality of input pad groups may further include a third input pad and a fourth input pad. The plurality of input terminals may include a plurality of third input terminals electrically connected to the third input pad of each input pad group of the plurality of input pad groups and a fourth input terminal electrically connected to the fourth input pad of each input pad group of the plurality of input pad groups.

A test device may be electrically connected to the printed circuit board, and the test device may measure a resistance between the second input pad of at least one input pad group of the plurality of input pad groups and the printed circuit board.

In accordance with another aspect of the present disclosure, there is provided a display module including: a display panel including an input pad group each including a first input pad, a grounded second input pad, a third input pad, and a fourth input pad; and a printed circuit board disposed on the display panel, the printed circuit board including a terminal test point structure comprising a plurality of input terminals connected to the input pad group, wherein the terminal test point structure comprises: a first input terminal electrically connected to the first input pad of the input pad group; a second input terminal electrically connected to the grounded second input pad and the third input pad of the input pad group; and a third input terminal electrically connected to the fourth input pad of the input pad group.

A test device may be electrically connected to the printed circuit board, and the test device may measure a magnitude of current flowing at a measurement point disposed between the first input pad and the grounded second input pad of the input pad group and may measure a voltage between the third input pad and the fourth input pad of the input pad group.

### BRIEF DESCRIPTION OF THE DRAWINGS

The accompanying drawings, which are included to provide a further understanding of the inventive concepts, and are incorporated in and constitute a part of this specification, illustrate exemplary embodiments of the inventive concepts, and, together with the description, serve to explain principles of the inventive concepts.

FIG. 1 is a plan view illustrating a display panel in accordance with an embodiment of the present disclosure.

FIG. 2 is a plan view illustrating a display module test system in accordance with an embodiment of the present disclosure.

FIG. 3 is a sectional view taken along line I-I′ shown in FIG. 1.

FIG. 4 is a sectional view taken along line II-II′ shown in FIG. 2.

FIG. 5 is a sectional view taken along line III-III′ shown in FIG. 2.

FIG. 6 is a perspective view illustrating a terminal test point structure in which a connection resistance may be measured in accordance with an embodiment of the present disclosure.

FIG. 7 is a plan view illustrating a terminal portion of a printed circuit board shown in FIG. 2.

FIG. 8 is a plan view schematically illustrating a first pad portion and output terminals in accordance with an embodiment of the present disclosure.

FIG. 9 is a plan view schematically illustrating a second pad portion and input terminals in accordance with an embodiment of the present disclosure.

FIG. 10 is a plan view schematically illustrating a first pad portion, a second pad portion, and input/output terminals in accordance with an embodiment of the present disclosure.

### DETAILED DESCRIPTION

Hereinafter, embodiments of the present disclosure will be described in more detail with reference to the accompanying drawings. Inventive concepts may be embodied in different forms and should not be construed as limited to embodiments set forth herein. Rather, embodiments are provided so that this disclosure will be thorough and complete, and will fully convey the scope of present description to those of ordinary skill in the art.

In the description, elements for understanding an operation according to the present disclosure are described. Descriptions of other elements may be omitted so that the subject matter may be clearly understood.

In the specification, when an element is referred to as being “connected” or “coupled” to another element, the element can be directly connected or coupled to another element or the element can be indirectly connected or coupled to another element with one or more intervening elements interposed therebetween. The technical terms used herein are used for the purpose of illustrating embodiments and are not intended to be limiting. It will be understood that when a component “includes” an element, unless there is another opposite description thereto, it should be understood that the component does not exclude another element and may further include one or more other elements. It will be understood that for the purposes of this disclosure, “at least one of X, Y, and Z” can be construed as X only, Y only, Z only, or any combination of two or more items X, Y, and Z (e.g., XYZ, XYY, YZ, ZZ). Similarly, for the purposes of this disclosure, “at least one selected from the group consisting of X, Y, and Z” can be construed as X only, Y only, Z only, or any combination of two or more items X, Y, and Z (e.g., XYZ, XYY, YZ, ZZ).

It will be understood that, although the terms “first”, “second,” etc. may be used herein to describe various elements, these elements should not be limited by these terms. These terms are only used to distinguish one element from another element. Thus, a “first” element discussed below could also be termed a “second” element without departing from the teachings of the present disclosure.

Spatially relative terms, such as “below,” “above,” and the like, may be used herein for ease of description to describe the relationship of one element to another element, as illustrated in the figures. It will be understood that the spatially relative terms, as well as the illustrated configurations, are intended to encompass different orientations of the apparatus in use or operation in addition to the orientations described herein and depicted in the figures. For example, if the apparatus in the figures is turned over, elements described as “below” or “beneath” other elements or features may then be oriented “above” the other elements or features. Thus, the exemplary term, “above,” may encompass both an orientation of above and below. The apparatus may be otherwise oriented (e.g., rotated 90 degrees or at other orientations) and the spatially relative descriptors used herein interpreted accordingly.

In the drawings, dimensions may be exaggerated for clarity of illustration. It will be understood that when an element is referred to as being “between” two elements, the element may be the only element between the two other elements, or one or more intervening elements may also be present. Like reference numerals refer to like elements throughout.

Embodiments of the disclosure are described here with reference to the drawings. Changes in the structures illustrated in the drawings are contemplated, and may be due to, for example, manufacturing technologies and/or tolerances. Embodiments of the present disclosure shall not be limited to the specific structures illustrated in the drawings. The regions shown in the drawings are schematic in nature, and the shapes thereof may not represent the actual shapes of the regions of the device, and may not limit the scope of the disclosure.

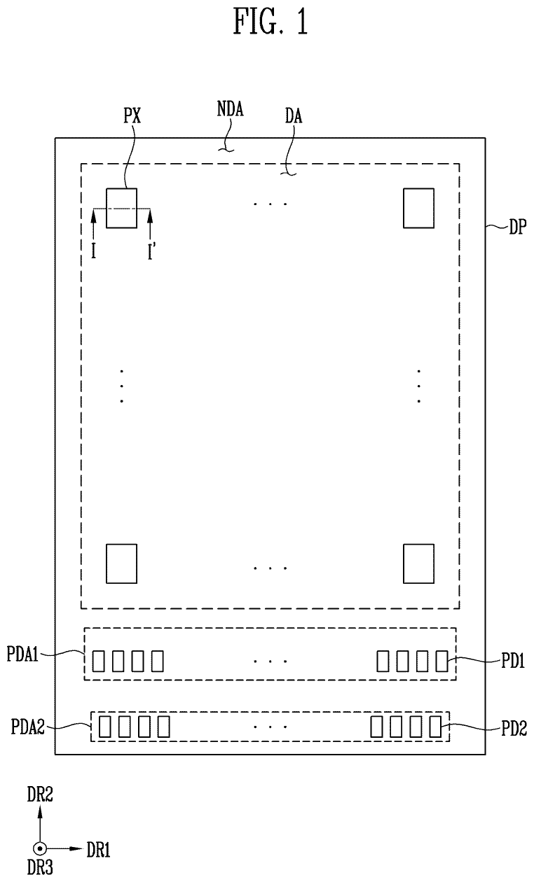

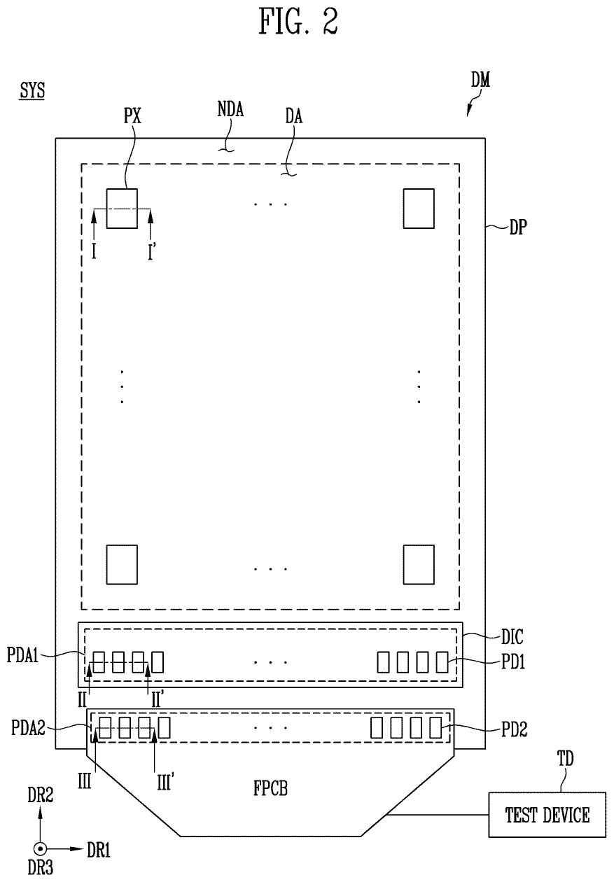

FIG. 1 is a plan view illustrating a display panel in accordance with an embodiment of the present disclosure. FIG. 2 is a plan view illustrating a display module test system in accordance with an embodiment of the present disclosure.

Referring to FIG. 1, the display panel DP may be a light emitting type display panel. However, the present disclosure is not limited thereto. For example, the display panel DP may be an organic light emitting display panel, a quantum dot light emitting display panel, or another display panel. In an example organic light emitting display panel, a light emitting layer includes an organic light emitting material. In an example quantum dot light emitting display panel, a light emitting layer includes a quantum dot and a quantum rod. Hereinafter, the display panel DP will be described as the organic light emitting display panel.

The display panel DP may include a display area DA and a non-display area NDA adjacent to the display area DA. The non-display area NDA may be an area in which any image is not displayed. In an example, the display area DA may be defined as an area in which pixels PX are disposed, to provide image information to an exterior, which may be perceived by users. The non-display area NDA may be a peripheral area of the display area DA, and may surround the display area DA. For example, the non-display area NDA may be defined as an area in which lines for driving the pixels PX and electronic components are disposed.

The non-display area NDA may include a first pad portion PDA1 and a second pad portion PDA2. The first pad portion PDA1 may include a plurality of output pads PD1. The second pad portion PDA2 may include a plurality of input pads PD2.

A plurality of pixels PX may be disposed in a matrix form along a first direction DR1 and a second direction DR2, which form a plane. For example, the first direction DR1 and the second direction DR2 may be orthogonal to each other. The pixels PX may display, for example, any one of a red color, a green color, or a blue color. However, the present disclosure is not limited thereto, and the pixels PX may display at least one of a white color, a cyan color, or a magenta color. In FIG. 1, it is illustrated that the pixels PX have a quadrangular shape. However, the present disclosure is not limited thereto, and the shape of the pixels PX may be variously changed to have, for example, a polygonal shape, a circular shape, or an elliptical shape.

Referring to FIG. 1 and FIG. 2, the display module test system SYS may include a display module DM and a test device TD. In addition, the display module DM may include the display panel DP, a driving circuit chip DIC, and a printed circuit board FPCB.

The driving circuit chip DIC may be disposed on the display panel DP. For example, the driving circuit chip DIC may be disposed in the non-display area NDA. The driving circuit chip DIC may provide a signal for driving of the display panel DP. For example, the driving circuit chip DIC may be a source driver integrated circuit, which may provide a data signal to a data line. However, the present disclosure is not limited thereto, and the driving circuit chip DIC may be a combined driver integrated circuit in which both a scan driving circuit and a timing control circuit may be integrated. In FIG. 2, one or more driving circuit chip DIC may be disposed on the display panel DP. For example, in some embodiments, a plurality of driving circuit chips DIC may be disposed on the display panel DP.

In an embodiment of the present disclosure, the driving circuit chip DIC may be disposed on the display panel DP in a Chip-On-Glass (COG) structure or a Chip-On-Plastic (COP) structure. For example, the driving circuit chip DIC may be disposed on the display panel DP in a COG structure or a COP structure, and may be disposed to overlap with the first pad portion PAD1. In the COP structure, the driving circuit chip DIC and the display area DA may be disposed on a surface of a substrate, and the substrate may be bent where the driving circuit chip DIC may be disposed below the display area DA. In the COG structure, the driving circuit chip DIC and the display area DA may be disposed on a surface of a substrate, and the driving circuit chip DIC may be disposed adjacent to the display area DA. However, the present disclosure is not limited thereto and the COP structure and COG structure may be variously implemented.

The printed circuit board FPCB may be disposed on the display panel. For example, the printed circuit board FPCB may be disposed on the display panel DP to overlap with the second pad portion PAD2. The printed circuit board FPCB may be electrically connected to the display panel DP through the second pad portion PAD2. In some embodiments, the printed circuit board FPCB may be electrically connected to the test device TD.

In this specification, “electrically connected” includes a structure directly connected between a first electrical component and a second electrical component and a structure connected through another electrical component.

The printed circuit board FPCB may be connected to an end of the display panel DP. The printed circuit board FPCB may be directly connected to signal lines disposed in the display panel DP or be connected to the driving circuit chip DIC. The printed circuit board FPCB may transfer a signal received from the outside to the display panel DP or the driving circuit chip DIC.

The printed circuit board FPCB may be a flexible printed circuit board. Accordingly, the printed circuit board FPCB may be bent in a third direction DR3 or the opposite direction of the third direction DR3.

In an embodiment of the present disclosure, the printed circuit board FPCB may be disposed on the display panel DP in a Film-On-Plastic (FOP) structure or a Film-On-Glass (FOG) structure. For example, the driving circuit chip may be disposed in a COP structure and the printed circuit board may be disposed in a FOP structure, or the driving circuit chip may be disposed in a COG structure and the printed circuit board may be disposed in a FOG structure. In the FOP structure, the printed circuit board FPCB and the display area DA may be disposed on a surface of a substrate, and the substrate may be bent where the printed circuit board FPCB may be disposed below the display area DA. In the FOG structure, the printed circuit board FPCB and the display area DA may be disposed on a surface of a substrate, and the printed circuit board FPCB may be bent around an end portion of the substrate. However, the present disclosure is not limited thereto and the FOP structure and FOG structure may be variously implemented.

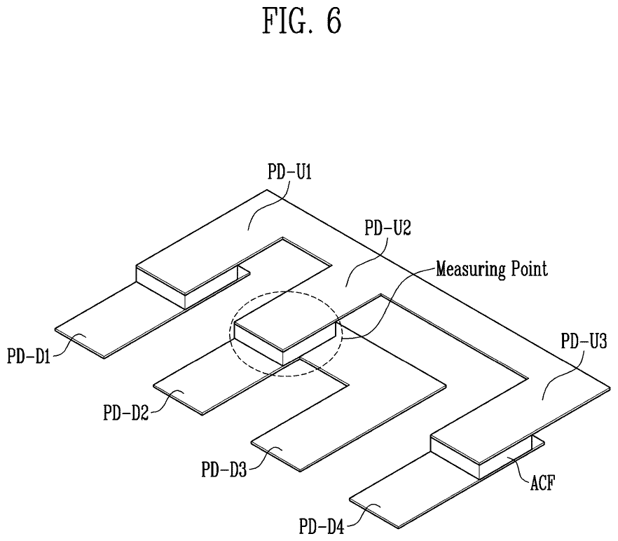

In an embodiment of the present disclosure, the display module test system SYS may measure a connection resistance between the first pad portion PDA1 and the driving circuit chip DIC. For example, during a test, the test device TD may be connected to the display panel DP and may apply an electrical signal to the display panel DP, and the display module test system SYS may measure a connection resistance between the first pad portion PDA1 and the driving circuit chip DIC. In an embodiment of the present disclosure, the display module test system SYS may measure a connection resistance between the second pad portion PDA2 and the printed circuit board FPCB. This will be described in detail later with reference to FIG. 6.

When a test is ended, the printed circuit board FPCB of the display panel DP may be connected to a control device, which may control an operation of the display panel DP. The test device TD may be disconnected from the display panel DP following a test.

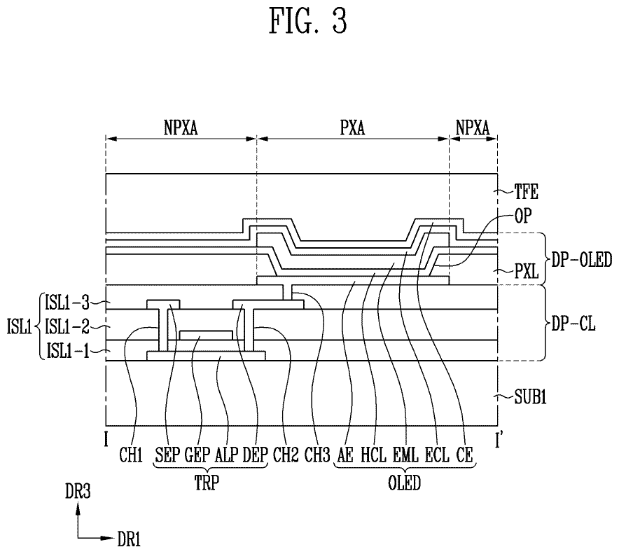

FIG. 3 is a sectional view taken along line I-I′ shown in FIG. 1.

Referring to FIG. 3, the display panel DP may include a first base substrate Sub1, a first layer DP-CL, a second layer DP-OLED, and a thin film encapsulation layer TFE.

The first layer DP-CL may include a plurality of conductive layers and a plurality of insulating layers, and the second layer DP-OLED may include a plurality of conductive layers and a plurality of functional organic layers.

The display area DA (see FIG. 1) of the display panel DP may include an emission area PXA and a non-emission area NPXA. The emission area PXA may be an area in which light generated in an organic light emitting element OLED is emitted in the third direction DR3. The non-emission area NPXA may be adjacent to the emission area PXA, and may be an area in which the light generated in the organic light emitting element OLED is not emitted in the third direction DR3.

A semiconductor pattern ALP of a pixel transistor TRP may be disposed on the first base substrate SUB1. The semiconductor pattern ALP may include amorphous silicon. For example, the amorphous silicon may be formed at low temperature. In an embodiment of the present disclosure, the semiconductor pattern ALP may include a metal oxide semiconductor. Although not separately illustrated, functional layers may be further disposed on a surface of the first base substrate SUB1. The functional layers may include at least one of a barrier layer or a buffer layer. The semiconductor pattern ALP may be disposed on the barrier layer or the buffer layer.

A first insulating member ISL1 may cover the pixel transistor TRP and may be disposed on the first base substrate SUB1. The first insulating member ISL1 may include a first insulating layer ISL1-1, a second insulating layer ISL1-2, and a third insulating layer ISL1-3.

The first insulating layer ISL1-1 may cover the semiconductor pattern ALP and may be disposed on the first base substrate SUB1. The first insulating layer ISL1-1 may include an organic layer and/or an inorganic layer. In particular, the first insulating layer ISL1-1 may include a plurality of inorganic thin films. The plurality of inorganic thin films may include a silicon nitride layer and a silicon oxide layer.

A control electrode GEP of the pixel transistor TRP may be disposed on the first insulating layer ISL1-1.

The second insulating layer ISL1-2 may cover the control electrode GEP and may be disposed on the first insulating layer ISL1-1. The second insulating layer ISL1-2 may include an organic layer and/or an inorganic layer. In particular, the second insulating layer ISL1-2 may include a plurality of inorganic thin films. The plurality of inorganic thin films may include silicon nitride or silicon oxide.

A source line and a power line may be disposed on the second insulating layer ISL1-2. An input electrode SEP and an output electrode DEP of the pixel transistor TRP may be disposed on the second insulating layer ISL1-2.

The input electrode SEP may be connected to the semiconductor pattern ALP through a first penetration hole CH1 penetrating the first insulating layer ISL1-1 and the second insulating layer ISL1-2. The output electrode DEP may be connected to the semiconductor pattern ALP respectively through a second penetration hole CH2 penetrating the first insulating layer ISL1-1 and the second insulating layer ISL1-2. Meanwhile, in an embodiment of the present disclosure, the pixel transistor TRP may be modified in a bottom gate structure.

The third insulating layer ISL1-3 may cover the input electrode SEP and the output electrode DEP may be disposed on the second insulating layer ISL1-2. The third insulating layer ISL1-3 may include an organic layer and/or an inorganic layer. In particular, the third insulating layer ISL-3 may include an organic material to provide a flat surface.

A pixel defining layer PXL and the organic light emitting element OLED may be disposed on the third insulating layer ISL1-3. An opening OP may be defined in the pixel defining layer PXL. The pixel defining layer PXL may be substantially similar to another insulating layer. The emission area PXA and the non-emission area NPXA may be distinguished from each other by the pixel defining layer PXL.

An anode AE may be connected to the output electrode DEP through a third penetration hole CH3 penetrating the third insulating layer ISL1-3. The opening OP of the pixel defining layer PXL may expose a portion of the anode AE. A hole control layer HCL may be commonly formed in the emission area PXA and the non-emission area NPXA. An organic light emitting layer EML and an electron control layer ECL may be sequentially formed on the hole control layer HCL. For example, the organic light emitting layer EML may be formed on the hole control layer HCL and the electron control layer ECL may be formed on the organic light emitting layer EML. A cathode CE may be commonly formed in the emission area PXA and the non-emission area NPXA. The cathode CE may be formed through, for example, a deposition or sputtering process according to a layer structure.

The thin film encapsulation layer TFE may be disposed over the cathode CE. The thin film encapsulation layer TFE may protect the organic light emitting element OLED from moisture and/or foreign matters.

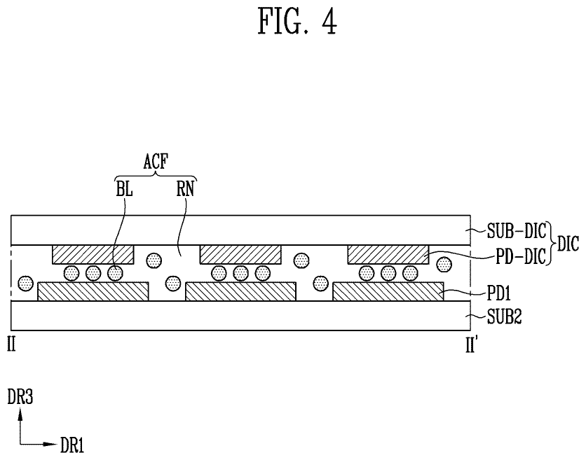

FIG. 4 is a sectional view taken along line II-II′ shown in FIG. 2. FIG. 4 illustrates a portion of a section taken along the line II-II′ shown in FIG. 2.

Referring to FIG. 4, output pads PD1 may be disposed on a second base member SUB2 of the display panel DP. In addition, driving pads PD-DIC may be disposed on a bottom of a base member DIC-SUB in the driving circuit chip DIC. The output pads PD1 and the driving pads PD-DIC may include a metal. Some of the driving pads PD-DIC may be short-circuited (shorted) with each other.

A conductive adhesive film ACF may allow the output pads PD1 and the driving circuit chip DIC to adhere to each other. For example, the conductive adhesive film ACF may be disposed between the output pads PD1 and the driving pads PD-DIC, which may allow the output pads PD1 and the driving circuit chip DIC to adhere to each other. The conductive adhesive film ACF may be an anisotropic conductive film.

The conductive adhesive film ACF may include a plurality of conductive balls BL and an insulative adhesive member RN.

Each of the plurality of conductive balls BL may be a conductive particle. The conductive particle may be capable of performing electrical conduction, and may use a conductive particle such as a metal or oxide thereof, a particle obtained by coating the metal or the oxide thereof on a surface, using an insulative material as a nucleus, or the like. Nickel (Ni), iron (Fe), copper (Cu), aluminum (Al), tin (Sn), zinc (Zn), chromium (Cr), cobalt (Co), silver (Ag), gold (Au), or the like may be used as the metal.

The insulative adhesive member RN may include an insulative polymer. The insulative polymer may include, for example, epoxy resin, acrylic resin, or the like. The epoxy resin may be configured with phenoxy polymer, which may have an iterative structure of bisphenol A and ether (—CO—C—) bonding, and may have an epoxy reactor at an end portion thereof. The acrylic resin may be configured with urethane (meta) acrylate polymer, which may have a urethane bonding (—NHCO—O) connection structure and may have an acrylate or methacrylate reactor at an end portion thereof.

The display module test system SYS may measure a connection resistance between the output pads PD1 and the driving circuit chip DIC. For example, the display module test system SYS may measure a connection resistance of the output pads PD1, the conductive balls BL, and the driving pads PD-DIC.

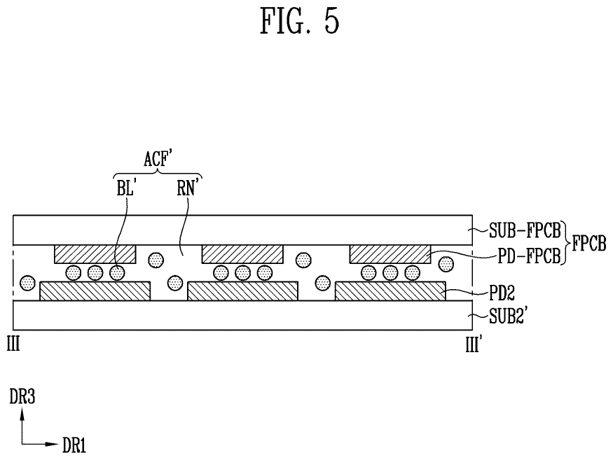

FIG. 5 is a sectional view taken along line III-III′ shown in FIG. 2. FIG. 5 illustrates a portion of a section taken along the line III-III′ shown in FIG. 2.

A second base member SUB2′ and a conductive adhesive film ACF′, which are shown in FIG. 5, may be substantially similar to the second base member SUB2 and the conductive adhesive film ACF, which are shown in FIG. 4. Hereinafter, repetitive descriptions may be omitted.

Referring to FIG. 5, input pads PD2 may be disposed on the second base member SUB2′ of the display panel DP. The input pads PD2 may include a metal.

The conductive adhesive film ACF′ may allow the input pads PD2 and the printed circuit board FPCB to adhere to each other. For example, the conductive adhesive film ACF′ may be disposed between the input pads PD2 and printed circuit board pads PD-FPCB. The conductive adhesive film ACF′ may allow the input pads PD2 and the printed circuit board FPCB to adhere to each other.

The display module test system SYS may measure a connection resistance between the input pads PD2 and the printed circuit board FPCB. For example, the display module test system SYS may measure a connection resistance of the input pads PD2, conductive balls BL′, and the printed circuit board pads PD-FPCB.

FIG. 6 is a perspective view illustrating a terminal test point structure in which a connection resistance may be measured in accordance with an embodiment of the present disclosure.

FIG. 6 illustrates an example in which lower pads PD-D1, PD-D2, PD-D3, and PD-D4, and upper pads PD-U1, PD-U2, and PD-U3 adhere to each other through a conductive adhesive film ACF. In an embodiment, the lower pads PD-D1, PD-D2, PD-D3, and PD-D4 shown in FIG. 6 may be the output pads PD1 shown in FIG. 4, and the upper pads PD-U1, PD-U2, and PD-U3 shown in FIG. 6 may be the driving pads PD-DIC shown in FIG. 4. In an embodiment, the lower pads PD-D1, PD-D2, PD-D3, and PD-D4 shown in FIG. 6 may be the input pads PD2 shown in FIG. 5, and the upper pads PD-U1, PD-U2, and PD-U3 shown in FIG. 6 may be the printed circuit board pads PD-FPCB shown in FIG. 5.

Referring to FIG. 6, the lower pads PD-D1, PD-D2, PD-D3, and PD-D4 include a first lower pad PD-D1, a second lower pad PD-D2, a third lower pad PD-D3, and a fourth lower pad PD-D4. The upper pads PD-U1, PD-U2, and PD-U3 include a first upper pad PD-U1, a second upper pad PD-U2, and a third upper pad PD-U3. The first lower pad PD-D1 may be connected to the first upper pad PD-U1. The second lower pad PD-D2 and the third lower pad PD-D3 may be connected to the second upper pad PD-U2. The fourth lower pad PD-D4 may be connected to the third upper pad PD-U3.

FIG. 6 illustrates an example in which the display module test system SYS may measure a connection resistance between the second lower pad PD-D2 and the second upper pad PD-U2.

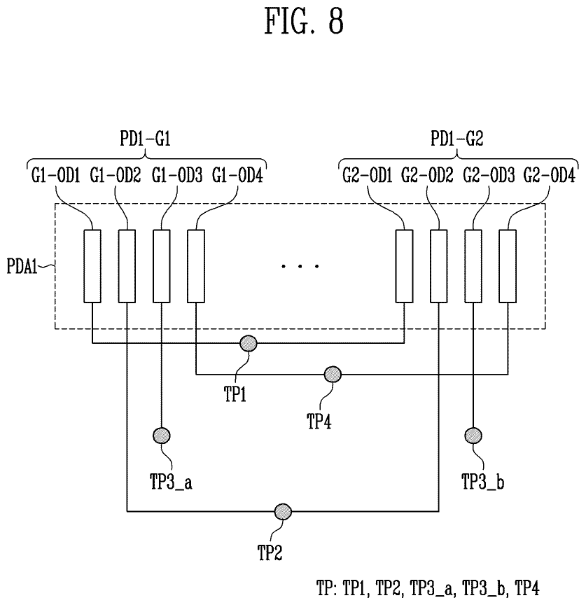

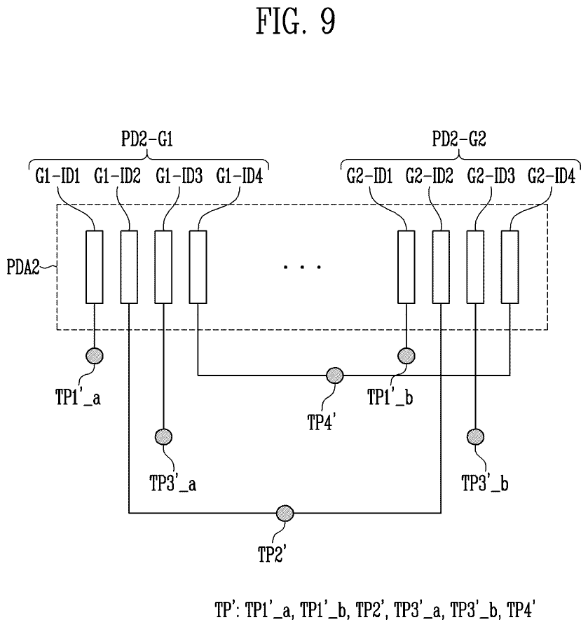

The first lower pad PD-D1 may be a current applied terminal, the second lower pad PD-D2 may be a current detection terminal, and the third lower pad PD-D3 and the fourth lower pad PD-D4 may be voltage applied terminals. For example, the test device TD may apply a current to the first lower pad PD-D1. For example, the test device TD may apply the current to the first lower pad PD-D1 via a plurality of output terminals TP (see FIG. 8) and/or a plurality of input terminals TP′ (see FIG. 9). The second lower pad PD-D2 may be in a ground state, and the current applied to the first lower pad PD-D1 may flow to the second lower pad PD-D2. Accordingly, the display module test system SYS (see FIG. 2) may measure a magnitude of current flowing at a measurement point. Also, the display module test system SYS may measure a voltage between the third lower pad PD-D3 and the fourth lower pad PD-D4.

In some embodiments, the display module test system SYS may measure a potential difference between the third lower pad PD-D3 and the fourth lower pad PD-D4, using a multi-meter, and measure a voltage of the measurement point (e.g., a voltage between the second lower pad PD-D2 and the second upper pad PD-U2). As such, the display module test system SYS may measure the current and the voltage at the measurement point. The display module test system SYS may calculate a connection resistance at the measurement point, for example, according to a relationship of voltage=current×resistance. For example, the resistance may be a value obtained by dividing the potential difference between the third lower pad PD-D3 and the fourth lower pad PD-D4 by the current flowing at the measurement point.

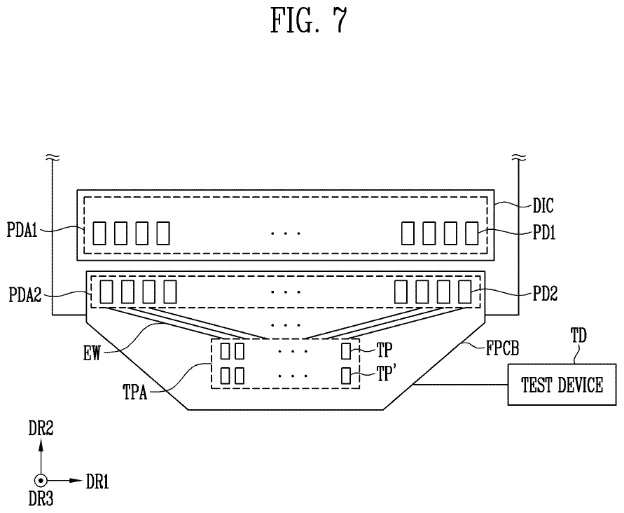

FIG. 7 is a plan view illustrating a terminal portion of the printed circuit board shown in FIG. 2.

Referring to FIG. 7, the printed circuit board FPCB may include a plurality of terminals TP and TP′. For example, the printed circuit board FPCB may include a plurality of terminals TP and TP′ disposed on a terminal portion TPA.

The plurality of terminals TP and TP′ may be connected to the test device TD. Accordingly, the test device TD may provide an electrical signal to the plurality of terminals TP and TP′. For example, the test device TD may apply a test current to the plurality of terminals TP and TP′ and may measure a connection resistance between the first pad portion PDA1 and the driving circuit chip DIC, or between the second pad portion PDA2 and the printed circuit board FPCB.

The plurality of terminals TP and TP′ may be connected to the first pad portion PDA1 and the second pad portion PDA2. For example, the printed circuit board FPCB may include a plurality of lines EW electrically connecting the terminal portion TPA to the first pad portion PDA1 and the second pad portion PDA2. Accordingly, the plurality of terminals TP and TP′ may supply the signal transferred from the test device TD to the first pad portion PDA1 and the second pad portion PDA2. For example, the plurality of terminals TP and TP′ may supply the test current to the first pad portion PDA1 and the second pad portion PDA2.

The plurality of terminals TP and TP′ may include output terminals TP and input terminals TP′. The output terminals TP and the input terminals TP′ may be arranged in parallel lines in a direction. For example, the output terminals TP may be arranged in a first direction D1 and the input terminals TP′ may be arranged parallel to the output terminals TP in the first direction D1. However, the present disclosure is not limited thereto. For example, the output terminals TP and the input terminals TP′ may be alternately arranged in the first direction D1 while alternating with each other in a second direction D2.

FIG. 8 is a plan view schematically illustrating a first pad portion and output terminals in accordance with an embodiment of the present disclosure.

Referring to FIG. 8, the first pad portion PDA1 may include a first output pad group PD1-G1 and a second output pad group PD1-G2. Although two output pad groups are illustrated as an example in FIG. 8, the present disclosure is not limited thereto.

Each of the output pad groups PD1-G1 and PD1-G2 may include a plurality of output pads PD1 (see FIG. 7). For example, the first output pad group PD1-G1 may include first to fourth output pads G1-OD1, G1-OD2, G1-OD3, and G1-OD4, and the second output pad group PD1-G2 may also include first to fourth output pads G2-OD1, G2-OD2, G2-OD3, and G2-OD4.

The first to fourth output pads G1-OD1, G1-OD2, G1-OD3, and G1-OD4 of the first output pad group PD1-G1, and the first to fourth output pads G2-OD1, G2-OD2, G2-OD3, and G2-OD4 of the second output pad group PD1-G2, may correspond to the lower pads PD-D1, PD-D2, PD-D3, and PD-D4 shown in FIG. 6, respectively.

Each of the output pad groups PD1-G1 and PD1-G2 may include a grounded output pad. For example, the first output pad group PD1-G1 may include a grounded second output pad G1-OD2, and the second output pad group PD1-G2 may include a ground second output pad G2-OD2.

The output terminals TP may be disposed on the terminal portion TPA (see FIG. 7). The terminal portions TP may include a first output terminal TP1, a second output terminal TP2, a third output terminal TP3_a, a fourth output terminal TP3_b, and a fifth output terminal TP4.

The first output terminal TP1 may receive an electrical signal transferred from the test device TD (see FIG. 7). For example, the first output terminal TP1 may receive a test current transferred from the test device TD.

The first output terminal TP1 may be connected to each of the first output pads G1-OD1 and G2-OD2 of the output pad groups PD1-G1 and PD1-G2. That is, the test device TD may supply the test current to the first output pads G1-OD1 and G2-OD2 through the first output terminal TP1.

The second output terminal TP2 may be connected to the second output pad G1-OD2 of the first output pad group PD1-G1 and the second output pad G2-OD2 of the second output pad group PD1-G2. The test current supplied to the first output terminal TP1 may flow to the second output terminal TP2. For example, the test current supplied to each of the first output pads G1-OD1 and G2-OD1 of the output pad groups PD1-G1 and PD1-G2 may flow to each of the grounded second output pad G1-OD2 of the first output pad group PD1-G1 and the grounded second output pad G2-OD2 of the second output pad group PD1-G2. The test current may flow to the second output terminal TP2 connected to the second output pads G1-OD1 and G2-OD2.

The third output terminal TP3_a may be connected to the third output pad G1-OD3 of the first output pad group PD1-G1. The fourth output terminal TP3_b may be connected to the third output pad G2-OD3 of the second output pad group PD1-G2.

The fifth output terminal TP4 may be connected to the fourth output pad G1-OD4 of the first output pad group PD1-G1 and the fourth output pad G2-OD4 of the second output pad group PD-G2.

The display module test system SYS may measure a connection resistance between each of the output pad groups PD1-G1 and PD1-G2 and the driving circuit chip DIC as described with reference to FIG. 6. For example, the display module test system SYS may measure a magnitude of the test current flowing from the first output terminal TP1 to the second output terminal TP2. After measuring the magnitude of the test current flowing from the first output terminal TP1 to the second output terminal TP2, the display module test system SYS may measure a potential difference between the third output pad G1-OD3 and the fourth output pad G1-OD4. A voltage between the second output pad G1-OD2 and the driving circuit chip DIC may be determined using the potential difference between the third output pad G1-OD3 and the fourth output pad G1-OD4. Accordingly, the display module test system SYS may measure a connection resistance between the second output pad G1-OD2 and the driving circuit chip DIC. For convenience of description, a method of measuring a connection resistance between the first output pad group PD1-G1 and the driving circuit chip DIC has been described, but the present disclosure is not limited thereto.

In accordance with an embodiment of the present disclosure, the design of the printed circuit board FPCB of the display module test system SYS can be improved. For example, the first output terminal TP1 may be connected to the first output pad G1-OD1 of the first output pad group PD1-G1 and the first output pad G2-OD1 of the second output pad group PD1-G2. In accordance with an embodiment of the present disclosure, the number of lines connected from the first output terminal TP1 to the first output pads G1-OD1 and G2-OD1 can be decreased.

When output terminals respectively connected to eight output pads are implemented, a space in which eight output terminals are to be disposed may be needed on the printed circuit board. In addition, the number of lines respectively connecting the eight output terminals and the eight output pads to each other may be relatively large.

In some embodiments, the output terminals TP may include five output terminals TP1, TP2, TP3_a, TP3_b, and TP4. Accordingly, the printed circuit board FPCB may need a relatively small space in which the output terminals TP are disposed. In addition, a relatively small space in which the output terminals TP and the output pad groups PD1-G1 and PD1-G2 are connected to each other may also be used. Thus, the printed circuit board FPCB in accordance with an embodiment of the present disclosure can be relatively readily designed.

FIG. 9 is a plan view schematically illustrating a second pad portion and input terminals in accordance with an embodiment of the present disclosure.

Referring to FIG. 9, the second pad portion PDA2 may include a plurality of input pad groups PD2-G1 and PD2-G2. For example, the second pad portion PDA2 may include a first input pad group PD2-G1 and a second input pad group PD2-G2. Although two input pad groups are illustrated in an example in FIG. 9, the present disclosure is not limited thereto.

Each of the input pad groups PD2-G1 and PD2-G2 may include a plurality of input pads PD2 (see FIG. 7). For example, the first input pad group PD2-G1 may include first to fourth input pads G1-ID1, G1-ID2, G1-ID3, and G1-ID4, and the second input pad group PD2-G2 may include first to fourth input pads G2-ID1, G2-ID2, G2-ID3, and G2-ID4.

The first to fourth input pads G1-ID1, G1-ID2, G1-ID3, and G1-ID4 of the first input pad group PD2-G1, and the first to fourth input pads G2-ID1, G2-ID2, G2-ID3, and G2-ID4 of the second input pad group PD2-G2, may correspond to the lower pads PD-D1, PD-D2, PD-D3, and PD-D4 shown in FIG. 6, respectively.

The input pad groups PD2-G1 and PD2-G2 may include grounded input pads G1-ID2 and G2-ID2, respectively. For example, the first input pad group PD2-G1 may include a grounded second input pad G1-ID2, and the second input pad group PD2-G2 may include a grounded second input pad G2-ID2.

The input terminals TP′ may be disposed on the terminal portion TPA (see FIG. 7). The input terminals TP′ may include a first input terminal TP1′_a, a second input terminal TP1_b, a third input terminal TP2′, a fourth input terminal TP3′_a, a fifth input terminal TP3_b, and a sixth input terminal TP4′.

The first input terminal TP1′_a and the second input terminal TP1′_b may receive an electrical signal transferred from the test device TD (see FIG. 7). For example, the first input terminal TP1′_a and the second input terminal TP1′_b may receive a test current transferred from the test device TD.

The first input terminal TP1′_a may be connected to the first input pad G1-ID1 of the first input pad group PD2-G1, and the second input terminal TP1′_b may be connected to the first input pad G2-ID1 of the second input pad group PD2-G2. The test device TD may supply the test current to the first input pads G1-ID1 and G2-ID1 respectively through the first input terminal TP1′_a and the second input terminal TP1′_b.

The third input terminal TP2′ may be connected to the second input pad G1-ID2 of the first input pad group PD2-G1 and the second input pad G2-ID2 of the second input pad group PD2-G2. The test current supplied to the first input terminal TP1′_a and the second input terminal TP1′_b may flow to the third input terminal TP2′. For example, the test current supplied to each of the first input pads G1-ID1 and G2-ID1 of the input pad groups PD2-G1 and PD2-G2 may flow to each of the grounded second input pad GI-ID2 of the first input pad group PD2-G1 and the grounded second input pad G2-ID2 of the second input pad group PD2-G2. Accordingly, the test current may flow to the third input terminal TP2′ connected to the second input pads G1-ID2 and G2-ID2 of the first input pad group PD2-G1 and the second input pad group PD2-G2, respectively.

The fourth input terminal TP3′_a may be connected to the third input pad G1-ID3 of the first input pad group PD2-G1 and the fifth input terminal TP3′_b may be connected to the third input pad G2-ID3 of the second input pad group PD1-G2.

The sixth input terminal TP4′ may be connected to the fourth input pad G1-ID4 of the first input pad group PD2-G1 and the fourth input pad G2-ID4 of the second input pad group PD2-G2.

The display module test system SYS may measure a connection resistance between each of the input pad groups PD2-G1 and PD2-G2 and the printed circuit board FPCB as described with reference to FIG. 6. For example, the display module test system SYS may measure a magnitude of the test current flowing from the first input terminal TP1′_a to the third input terminal TP2′. After measuring the magnitude of the test current flowing from the first input terminal TP1′_a to the third input terminal TP2′, the display module test system SYS may measure a potential difference between the third input pad G1-ID3 and the fourth input pad G1-ID4. A voltage between the second input pad G1-ID2 and the printed circuit board FPCB may be determined using the potential difference between the third input pad G1-ID3 and the fourth input pad G1-ID4. Accordingly, the display module test system SYS may measure a connection resistance between the second input pad G1-ID2 and the printed circuit board FPCB. For convenience of description, a method of measuring a connection resistance between the first input pad group PD2-G1 and the printed circuit board FPCB has been described, but the present disclosure is not limited thereto.

In accordance with an embodiment of the present disclosure, the design of the printed circuit board FPCB of the display module test system SYS can be improved. For example, the design of the printed circuit board FPCB may be simplified. For example, the third input terminal TP2′ may be connected to the second input pad G1-ID2 of the first input pad group PD2-G1 and the second input pad G2-ID2 of the second input pad group PD2-G2. Accordingly, the number of lines connected from the third input terminal TP2′ to the second input pads G1-ID2 and G2-ID2 can be decreased. Accordingly, the printed circuit board FPCB may use a relatively small space in which the input terminals TP′ are disposed. In addition, a relatively small space in which lines connecting the input terminals TP′ to the first input pad group PD2-G1 and the second input pad group PD2-G2 are disposed may also be used. Thus, the printed circuit board FPCB in accordance with an embodiment of the present disclosure can be relatively readily designed.

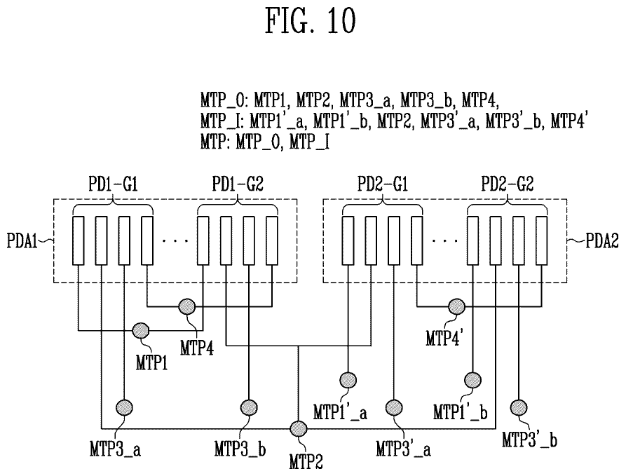

FIG. 10 is a plan view schematically illustrating a first pad portion, a second pad portion, and input/output terminals in accordance with an embodiment of the present disclosure.

Referring to FIG. 10, the first pad portion PDA1 may include a plurality of output pad groups PD1-G1 and PD1-G2, and the second pad portion PDA2 may include a plurality of input pad groups PD2-G1 and PD2-G2.

The first pad portion PDA1 and the second pad portion PDA2, which are shown in FIG. 10, may be substantially similar to the first pad portion PDA1 shown in FIG. 8 and the second pad portion PDA2 shown in FIG. 9, respectively.

In addition, a first input/output terminal MTP1, a third input/output terminal MTP3_a, a fourth input/output terminal MTP3_b, and a fifth input/output terminal MTP4 of a first input/output terminal group MTP_0 shown in FIG. 10 may be substantially similar to the first output terminal TP1, the third output terminal TP3_a, the fourth output terminal TP3_b, and the fifth output terminal TP4, which are shown in FIG. 8, respectively.

Moreover, a first input/output terminal MTP1′_a, a second input/output terminal MTP1′_b, a fourth input/output terminal MTP3′_a, a fifth input/output terminal MTP3′_b, and a sixth input/output terminal MTP4′ of a second input/output terminal group MTP_1 shown in FIG. 10 may be substantially similar to the first input terminal TP1′_a, the second input terminal TP1′_b, the fourth input terminal TP3′_a, the fifth input terminal TP3′_b, and the sixth input terminal TP4′, which are shown in FIG. 9, respectively.

An input/output terminal group MTP may be disposed on the terminal portion TPA (see FIG. 7) of the printed circuit board FPCB (see FIG. 7). The input/output terminal group MTP may include the first input/output terminal group MTP_0 and the second input/output terminal group MTP_1.

The first input/output terminal group MTP_0 may include the first input/output terminal MTP1, a second input/output terminal MTP2, the third input/output terminal MTP3_a, the fourth input/output terminal MTP3_b, and the fifth input/output terminal MTP4.

The second input/output terminal group MTP_1 may include the first input/output terminal MTP1′_a, the second input/output terminal MTP1′_b, a third input/output terminal MTP2, the fourth input/output terminal MTP3′_a, the fifth input/output terminal MTP3′_b, and the sixth input/output terminal MTP4′.

The first input/output terminal MTP1 of the first input/output terminal group MTP_0 may be connected to each of the first output pads G1-OD1 and G2-OD1 (see FIG. 8) of the output pad groups PD1-G1 and PD1-G2. In addition, the first input/output terminal MTP1′_a of the second input/output terminal group MTP_1 may be connected to the first input pad G1-ID1 (see FIG. 9) of the input pad group PD2-G1 and the second input/output terminal MTP1′_b of the second input/output terminal group MTP_1 may be connected to the first input pad G2-ID1 (see FIG. 9) of the input pad group PD2-G2.

The first input/output terminal MTP1 of the first input/output terminal group MTP_0 may receive an electrical signal transferred from the test device TD (see FIG. 7). For example, the first input/output terminal MTP1 of the first input/output terminal group MTP_0 may receive a test current transferred from the test device TD.

In addition, the first input/output terminal MTP′_a and the second input/output terminal MTP′_b of the second input/output terminal group MTP_1 may receive an electrical signal transferred from the test device TD. For example, the first input/output terminal MTP′_a and the second input/output terminal MTP′_b of the second input/output terminal group MTP_1 may receive a test current transferred from the test device TD.

The second input/output terminal MTP2 may be connected to each of the second output pads G1-OD2 and G2-OD2 (see FIG. 8) of the output pad groups PD1-G1 and PD1-G2 and the second input pads G1-ID2 and G2-ID2 (see FIG. 9) of the input pad groups PD2-G1 and PD2-G2.

The third input/output terminal MTP3_a of the first input/output terminal group MTP_0 may be connected to the third output pad G1-OD3 (see FIG. 8) of the first output pad group PD1-G1 and the fourth input/output terminal MTP3_b of the first input/output terminal group MTP_0 may be connected to the third output pad G2-OD3 (see FIG. 8) of the second output pad group PD1-G2.

The fifth input/output terminal MTP4 of the first input/output terminal group MTP_0 may be connected to the fourth output pad G1-OD4 of the first output pad group PD1-G1 and the fourth output pad G2-OD4 of the second output pad group PD1-G2.

The fourth input/output terminal MTP3′_a of the second input/output terminal group MTP_1 may be connected to the third input pad G1-ID3 (see FIG. 9) of the first input pad group PD2-G1 and the fifth input/output terminal MTP3′_b of the second input/output terminal group MTP_1 may be connected to the third input pad G2-ID3 (see FIG. 9) of the second input pad group PD2-G2.

The sixth input/output terminal MTP4′ of the second input/output terminal group MTP_1 may be connected to the fourth input pad G1-ID4 of the first input pad group PD2-G1 and the fourth input pad G2-ID4 of the second input pad group PD2-G2.

In accordance with an embodiment of the present disclosure, the design of the printed circuit board FPCB of the display module test system SYS can be improved. For example, the design of the printed circuit board FPCB may be simplified. In some embodiments, the printed circuit board FPCB may include eleven input/output terminals.

When input/output terminals are respectively connected to eight output pads disposed on the first pad portion PDA1 and eight input pads disposed on the second pad portion PDA2, a space in which sixteen input/output terminals and lines respectively extending from the sixteen input/output terminals are disposed may be used.

On the other hand, the input/output terminal group MTP in accordance with an embodiment of the present disclosure includes eleven input/output terminals, and hence the printed circuit board FPCB can be relatively readily designed.

In accordance with the present disclosure, there can be provided a display module test system including a printed circuit board having an improved design. For example, a display module including a printed circuit board may have a simplified design.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims.

What is claimed is:

1. A display module comprising:
a display panel including a plurality of output pad groups each output pad group of the plurality of output pad groups including a first output pad;
a driving circuit chip disposed on the display panel and overlapping the plurality of output pad groups; and
a printed circuit board disposed on the display panel, the printed circuit board including a plurality of output terminals electrically connected to the plurality of output pad groups,
wherein the plurality of output terminals include a first output terminal electrically connected to the first output pad of each of the plurality of output pad groups.

2. The display module of claim 1, wherein each output pad group of the plurality of output pad groups includes a grounded second output pad.

3. The display module of claim 2, wherein the plurality of output terminals further include a second output terminal electrically connected to the grounded second output pad of each output pad group of the plurality of output pad groups, and
wherein a current is supplied to the first output pad of each of the plurality of output pad groups through the first output terminal flows from the first output terminal to the second output terminal.

4. The display module of claim 3, wherein each output pad group of the plurality of output pad groups includes a third output pad and a fourth output pad, and
wherein the plurality of output terminals include a plurality of third output terminals electrically connected to the third output pad of each of the plurality of output pad groups and a fourth output terminal electrically connected to the fourth output pad of each of the plurality of output pad groups.

5. The display module of claim 4, further comprising a test device electrically connected to the printed circuit board,
wherein the test device measures a resistance between the grounded second output pad of at least one output pad group of the plurality of output pad groups and the driving circuit chip.

6. The display module of claim 5, wherein the test device measures, as the resistance, a value obtained by dividing a potential difference between at least one of the plurality of fourth output pads and at least one of the plurality of third output pads by the current.

7. The display module of claim 3, wherein the display panel further includes a plurality of input pad groups each including a first input pad,
wherein the printed circuit board includes a plurality of input terminals connected to the plurality of input pad groups, and
wherein the input terminals include a plurality of first input terminals electrically connected to the first input pad of each input pad group of the plurality of input pad groups.

8. The display module of claim 7, wherein a current is supplied to the first input pad of each input pad group of the plurality of input pad groups through the plurality of first input terminals.

9. The display module of claim 8, wherein each of the input pad groups includes a grounded second input pad.

10. The display module of claim 9, wherein the plurality of input terminals further include a second input terminal electrically connected to the second input pad of each input pad group of the plurality of input pad groups, and
wherein the current flows from the plurality of first input terminals to the second input terminal.

11. The display module of claim 10, wherein the second output terminal and the second input terminal are a same terminal.

12. The display module of claim 11, wherein each input pad group of the plurality of input pad groups includes a third input pad and a fourth input pad, and
wherein the plurality of input terminals include a plurality of third input terminals electrically connected to the third input pad of each input pad group of the plurality of input pad groups and a fourth input terminal electrically connected to the fourth input pad of each input pad group of the plurality of input pad groups.

13. The display module of claim 12, further comprising a test device electrically connected to the printed circuit board,
wherein the test device measures a resistance between the second input pad of at least one input pad group of the plurality of input pad groups and the printed circuit board.

14. The display module of claim 13, wherein the test device measures, as the resistance, a value obtained by dividing a potential difference between at least one of the fourth input pads and at least one of the third input pads by the current.

15. The display module of claim 1, wherein the driving circuit chip is disposed in a Chip-On-Plastic (COP) structure or a Chip-On-Glass (COG) structure, and
wherein the printed circuit board is disposed in a Film-On-Plastic (FOP) structure or a Film-On-Glass (FOG) structure.

16. A display module comprising:
a display panel including a plurality of input pad groups each including a first input pad and a grounded second input pad; and
a printed circuit board disposed on the display panel, the printed circuit board including a plurality of input terminals connected to the plurality of input pad groups,
wherein the plurality of input terminals include a plurality of first input terminals electrically connected to the first input pad of each input pad group of the plurality of input pad groups and a second input terminal electrically connected to the second grounded input pad of each input pad group of the plurality of input pad groups.

17. The display module of claim 16, wherein each input pad group of the plurality of input pad groups further includes a third input pad and a fourth input pad, and
wherein the plurality of input terminals include a plurality of third input terminals electrically connected to the third input pad of each input pad group of the plurality of input pad groups and a fourth input terminal electrically connected to the fourth input pad of each input pad group of the plurality of input pad groups.

18. The display module of claim 16, further comprising a test device electrically connected to the printed circuit board,
wherein the test device measures a resistance between the second input pad of at least one input pad group of the plurality of input pad groups and the printed circuit board.

19. A display module comprising:
a display panel including an input pad group each including a first input pad, a grounded second input pad, a third input pad, and a fourth input pad; and
a printed circuit board disposed on the display panel, the printed circuit board including a terminal test point structure comprising a plurality of input terminals connected to the input pad group,
wherein the terminal test point structure comprises:
a first input terminal electrically connected to the first input pad of the input pad group;
a second input terminal electrically connected to the grounded second input pad and the third input pad of the input pad group; and
a third input terminal electrically connected to the fourth input pad of the input pad group.

20. The display module of claim 19, further comprising a test device electrically connected to the printed circuit board,
wherein the test device measures a magnitude of current flowing at a measurement point disposed between the first input pad and the grounded second input pad of the input pad group and measures a voltage between the third input pad and the fourth input pad of the input pad group.
